(19) United States
(12) Patent Application Publication
(10) Pub. No.: US 2024/0235157 A1
(43) Pub. Date: Jul. 11, 2024

(54) LASER ELEMENT AND ELECTRONIC DEVICE

(71) Applicant: SONY GROUP CORPORATION, TOKYO (JP)

(72) Inventor: GO HIRANO, TOKYO (JP)

(21) Appl. No.: 18/559,665

(22) PCT Filed: May 26, 2021
(86) PCT No.: PCT/JP2021/020071

§ 371 Date: Nov. 8, 2023

(51) Int. Cl. H01S 5/183; H01S 3/094; H01S 3/113; H01S 3/16; H01S 5/343

(52) U.S. Cl. CPC H01S 5/18305; H01S 3/094038; H01S 3/113; H01S 3/1618; H01S 3/1643; H01S 5/18361; H01S 5/34313

(57) ABSTRACT

Diffraction loss during laser resonance is inhibited. A laser element includes: a laminated semiconductor layer including a first reflection layer with respect to a first wavelength and an active layer that performs surface emission at the first wavelength; a laser medium disposed on a rear side of an optical axis of the laminated semiconductor layer and including a second reflection layer with respect to a second wavelength on a first surface facing the laminated semiconductor layer and a third reflection layer with respect to the first wavelength on a second surface on a side opposite to the first surface; a fourth reflection layer with respect to the second wavelength disposed on the second surface or disposed on a rear side of the optical axis with respect to the second surface; a first resonator that causes light of the first wavelength to resonate between the first reflection layer and the third reflection layer; and a second resonator that causes light of the second wavelength to resonate between the second reflection layer and the fourth reflection layer. The first resonator includes an optical element that condenses the light of the first wavelength in an optical axis direction, and the optical axis of the laminated semiconductor layer, an optical axis of the laser medium, and an optical axis of the optical element are coaxially arranged.

### TECHNICAL FIELD

The present disclosure relates to a laser element and an electronic device.

### BACKGROUND ART

The peak power of a laser is defined as the pulse energy divided by the pulse width, and in order to achieve higher peak power, it is important to obtain a shorter pulse width. A Q-switched solid-state laser that outputs a laser pulse has a feature that the length of its own resonator is proportional to the obtained pulse width, and the minimum resonator length is determined by the length of the used solid-state laser medium. The length of the solid-state laser medium installed in the resonator as a gain medium is determined by the amount of excitation light absorbed. Thus, when the length of the solid-state laser medium is simply reduced, the excitation light cannot be sufficiently absorbed, leading to a significant decrease in excitation efficiency.

Therefore, in the conventional method of externally exciting a Q-switched solid-state laser medium with a semiconductor laser, it is not preferable to make the length of the solid-state laser medium shorter than the absorption length of excitation light, and a shorter pulse cannot be obtained. That is, reducing the length of the solid-state laser medium in order to obtain a short pulse width leads to a decrease in the amount of excitation light absorbed and a decrease in excitation efficiency. In contrast, increasing the length of the solid-state laser medium in order to increase the amount of excitation light absorbed leads to a longer resonator length and an extended pulse width, and hence such a trade-off exists in the conventional method.

Meanwhile, in terms of manufacturing and the stability of light source output, the conventional Q-switched solid-state laser requires assembly adjustment by high-precision positioning of a plurality of optical elements, thus reducing mass productivity and making cost reduction difficult, and also posing challenges in the stability light source output due to positional displacement of each optical element.

Conventionally, for example, there is known a method of generating a short-pulse laser by externally exciting a Q-switched solid-state laser using a semiconductor laser (cf. Patent Documents 1 and 2). Since the obtained pulse width is proportional to the resonator length of the Q-switched solid-state laser, it is desirable to reduce the resonator length to obtain a shorter pulse width in order to obtain higher laser peak power.

However, in the conventional method, the thickness of the solid-state laser medium that can be used is limited by the absorption length determined by the wavelength of a semiconductor laser for excitation and the absorption coefficient of the solid-state laser medium at the wavelength. For example, in the case of Nd:YAG (10 at %) that is generally most often used in a Q-switched solid-state laser, the absorption length for excitation light having a wavelength of 808 nm is about 10 mm. When the length of the solid-state laser medium is made shorter than this length, the remaining excitation light that has not been absorbed returns to the semiconductor laser side to make the operation unstable or cause heat generation. For disk lasers, a method of folding back excitation light several times has also been proposed, but the method requires a complicated excitation optical system and poses challenges in size reduction and low cost.

Furthermore, conventionally, in order to reduce the size of a laser light source, for example, as disclosed in Patent Document 3, a method of integrally laminating a surface-emitting laser (vertical cavity surface-emitting laser (VCSEL)) for excitation and a solid-state laser medium has been proposed. However, there is only a description of “integrally laminating”, and no specific description of whether light transmission surfaces are bonded to each other, which bonding process is used, and how to solve problems caused by the process.

### CITATION LIST

### Patent Document

Patent Document 1: Japanese Patent Application Laid-Open No. 2013-219232
Patent Document 2: Japanese Patent Application Laid-Open No. 2019-176119
Patent Document 3: Japanese Patent Application Laid-Open No. 2007-173393

### SUMMARY OF THE INVENTION

### Problems to be Solved by the Invention

To further reduce the pulse width of the laser light, for example, it is conceivable for the excitation laser and the Q-switched solid-state laser to share a resonator. In this case, the resonator length can be made shorter on the Q-switched solid-state laser side, but the resonator length becomes long on the excitation laser side due to resonation involving the solid-state laser medium. When the resonator length increases, the diffraction loss generally increases, so that the light density in the semiconductor resonator decreases. That is, when the resonator length on the surface-emitting laser side increases, the excitation light density in the solid-state laser medium decreases. This leads to a reduction in the output of the solid-state laser.

Therefore, the present disclosure provides a laser element and an electronic device capable of inhibiting diffraction loss at the time of laser resonance.

### Solutions to Problems

In order to solve the above problems, according to the present disclosure, there is provided a laser element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer; and
a second resonator that causes light of the second wavelength to resonate between the second reflection layer and the fourth reflection layer,
in which
the first resonator includes an optical element that condenses the light of the first wavelength in an optical axis direction, and
the optical axis of the laminated semiconductor layer, an optical axis of the laser medium, and an optical axis of the optical element are arranged coaxially.

The optical element may include a concave mirror.

The concave mirror may have a multilayer film structure formed by layering at least one of a semiconductor material, a metal material, or a dielectric material.

At least one of the first reflection layer or the third reflection layer may include the concave mirror.

The laminated semiconductor layer may include a first semiconductor layer in which an end face on a side of the first reflection layer has a concave shape, and the concave mirror may be laminated on the first semiconductor layer.

An end face of the laser medium on a side of the third reflection layer may have a concave shape, and the concave mirror may be laminated on the end face of the laser medium.

The optical element may be bonded to an end face of the laser medium on a side opposite to a side facing the laminated semiconductor layer.

The optical element may include a first transparent material layer that transmits light of the second wavelength, a first end face of the first transparent material layer bonded to the laser medium may be a flat surface, and a second end face opposite to the first end face has a concave shape, and the concave mirror may be disposed along the second end face.

The laser element may further include a second transparent material layer that is bonded to the second end face of the first transparent material layer and transmits the light of the second wavelength, and in an end face of the second transparent material layer on a side opposite to a bonding surface to the first transparent material layer may be a flat surface.

The optical element may include a light refracting member that refracts incident light in an optical axis direction.

The laminated semiconductor layer may include a fifth reflection layer that is disposed closer to the laser medium than the active layer and transmit a part of the light of the first wavelength, and the light refracting member may be disposed between the fifth reflection layer and the second reflection layer.

The light refracting member may have an end face having a convex shape on a side of the laminated semiconductor layer facing the laser medium.

The optical element may be bonded to an end face of the laminated semiconductor layer on a side facing the laser medium, and the light refracting member may have one end face having a convex shape on a side facing the laser medium of the optical element.

The optical element may include a transparent material layer that is bonded to the light refracting member and transmits light of the first wavelength, the transparent material layer may have a refractive index smaller than a refractive index of the light refracting member, and a bonding surface of the transparent material layer to the light refracting member may have a concave shape, an end face on an opposite side of the bonding surface is a flat surface, and an end face of the laser medium may be bonded to the flat surface.

The light refracting member may have an end face having a convex shape on a side of the laser medium facing the laminated semiconductor layer.

The second reflection layer may be disposed along an end face of the convex shape.

The optical element may include a transparent material layer that is bonded to the light refracting member and transmits light of the first wavelength, and a bonding surface of the transparent material layer to the light refracting member may have a concave shape, an end face on an opposite side of the bonding surface may be a flat surface, and an end face of the laminated semiconductor layer may be bonded to the flat surface.

A part of the semiconductor layer including the active layer in the laminated semiconductor layer may be divided into a plurality of divided regions by an insulator, and each of the plurality of divided regions may include the first resonator and the second resonator.

The laser element may further include a saturable absorber including the fourth reflection layer on a third surface on a side opposite to the laser medium, the optical axis of the laminated semiconductor layer, the optical axis of the laser medium, an optical axis of the saturable absorber, and the optical axis of the optical element may be coaxially arranged, and the laminated semiconductor layer, the laser medium, and the saturable absorber may be integrally bonded.

In order to solve the above problems, according to the present disclosure, there is provided an electronic device including:
a laser element; and
a control unit that performs control to emit light from the laser element,
in which
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer, and
a second resonator that causes light of the second wavelength to resonate between the second reflection layer and the fourth reflection layer,
the first resonator includes an optical element that condenses the light of the first wavelength in an optical axis direction, and
the optical axis of the laminated semiconductor layer, an optical axis of the laser medium, and an optical axis of the optical element are coaxially arranged.

### BRIEF DESCRIPTION OF DRAWINGS

FIG. 1 is a diagram illustrating a basic configuration of a laser element according to the present disclosure.

FIG. 2 is a cross-sectional view of a laser element according to a first specific example.

FIG. 3 is a cross-sectional view of a laser element according to a second specific example.

FIG. 4 is a cross-sectional view of a laser element according to a third specific example.

FIG. 5 is a cross-sectional view of a laser element according to a fourth specific example.

FIG. 6 is a cross-sectional view of a laser element according to a fifth specific example.

FIG. 7 is a cross-sectional view of a laser element according to a sixth specific example.

FIG. 8 is a cross-sectional view of a laser element according to a seventh specific example.

FIG. 9 is a cross-sectional view of a laser element according to an eighth specific example.

FIG. 10 is a cross-sectional view of a laser element according to a ninth specific example.

FIG. 11 is a view schematically illustrating a manufacturing process of the laser element of the present disclosure.

FIG. 12 is a diagram illustrating a laser element in which a first transparent medium is disposed between an excitation light source and a solid-state laser medium.

FIG. 13 is a diagram illustrating a basic configuration of a laser element not including a saturable absorber.

FIG. 14 is a diagram illustrating an example of a schematic configuration of an endoscope system.

FIG. 15 is a block diagram illustrating an example of a functional configuration of a camera and a camera control unit (CCU) illustrated in FIG. 14.

FIG. 16 is a diagram illustrating an example of a schematic configuration of a microscopic surgery system.

### MODE FOR CARRYING OUT THE INVENTION

Hereinafter, an embodiment of a laser element will be described with reference to the drawings. Although the principal components of the laser element will be mainly described hereinafter, the laser element may include components and have functions that are not illustrated or described. The following description does not exclude configuration parts and functions that are not illustrated or described.

### Technical Features of Laser Element According to Present Disclosure

First, technical features of a laser element according to the present disclosure will be described before descriptions of an internal configuration and an operation of the laser element according to the present disclosure.

A laser element according to the present disclosure has a configuration in which a structure using a part of a surface-emitting laser as an excitation light source and a solid-state laser medium for Q-switching are integrally bonded. Note that, as described later, the laser element according to the present disclosure may include a laser element not having a Q-switching function, but a laser element having the Q-switching function will be first described.

In the laser element according to the present disclosure, the solid-state laser medium for Q-switching is shared by two resonators. These two resonators include a first resonator that resonates at a first wavelength and a second resonator (also referred to as a Q-switched solid-state laser resonator) that resonates at a second wavelength.

Since the two resonators share the solid-state laser medium, high-intensity excitation of the solid-state laser medium can be performed in the first resonator even when the solid-state laser medium is reduced, and a laser pulse having a shorter pulse width can be generated.

Furthermore, the laser element according to the present disclosure is an integrated laminated structure that can be fabricated by using a semiconductor process technology, and is thus excellent in mass productivity as well as laser output stability.

Here, the excitation light source is a form of a surface-emitting laser (vertical cavity surface-emitting laser (VCSEL)). This is different from the VCSEL in that at least one of mirrors forming the resonator is provided outside a laminated semiconductor layer, which is a main body of the excitation light source. As described later, the laser element according to the present disclosure has a structure in which the solid-state laser medium is disposed between the laminated semiconductor layer and the mirror disposed outside the laminated semiconductor layer.

In the laser element according to the present disclosure, since the light of the first wavelength resonates between the laminated semiconductor layer and the solid-state laser medium, the resonator length is longer than that when the light is resonated only with the laminated semiconductor layer. Thus, as described above, the diffraction loss increases, and the excitation light density in the solid-state laser medium decreases. Therefore, the laser element according to the present disclosure is provided with an optical element for inhibiting diffraction loss.

The laser element according to the present disclosure has the following three features.
(1) The first resonator and the second resonator share the solid-state laser medium. The first resonator includes the excitation light source and the solid-state laser medium. The second resonator includes the solid-state laser medium and a saturable absorber, and performs Q-switched laser oscillation using excitation light from the first resonator.
(2) An optical element that condenses the light of the first wavelength in the optical axis direction is provided inside the first resonator. This optical element has, for example, a concave mirror. The concave mirror is at least one of a first reflection layer or a third reflection layer provided on both sides of the first resonator. Alternatively, the optical element includes, for example, a light refracting member. The light refracting member refracts the incident light in the optical axis direction. The light refracting member is provided between a fifth reflection layer (also referred to as an intermediate mirror) in the laminated semiconductor layer and a second reflection surface of the laser medium.
(3) The excitation light source, the solid-state laser medium, and the saturable absorber have an integrated structure.

In the laser element according to the present disclosure, the solid-state laser medium in the first resonator absorbs the excitation light generated by injecting a current into the excitation light source. The solid-state laser medium forms the second resonator together with the saturable absorber installed adjacent to the first resonator. When the solid-state laser medium comes into a sufficiently excited state, and an output of spontaneous emission light increases above a certain threshold, a light absorption rate in the saturable absorber rapidly decreases, and the spontaneous emission light generated in the solid-state laser medium can be transmitted through the saturable absorber, causing induced emission in the solid-state laser medium. This results in Q-switched pulse oscillation.

### (Basic Configuration of Laser Element)

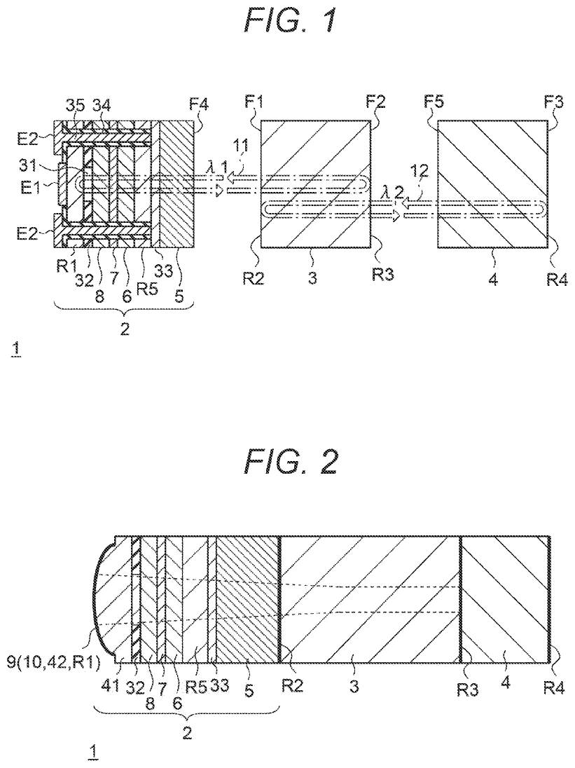

A specific embodiment of the laser element according to the present disclosure will be described below. FIG. 1 is a diagram illustrating a basic configuration of a laser element 1 according to the present disclosure. The laser element 1 of FIG. 1 has a configuration in which an excitation light source 2, a solid-state laser medium 3, and a saturable absorber 4 are integrally bonded.

The excitation light source 2 is a partial structure of VCSEL described above and includes the laminated semiconductor layer having a laminated structure. Hereinafter, the excitation light source 2 is sometimes referred to as a laminated semiconductor layer 2. The excitation light source 2 in FIG. 1 has a structure obtained by laminating a substrate 5, an n-contact layer 33, a fifth reflection layer R5, a cladding layer 6, an active layer 7, a cladding layer 8, a pre-oxidation layer 31, and a first reflection layer R1 in this order. Note that the laser element 1 of FIG. 1 has a bottom emission type configuration in which continuous wave (CW) excitation light is emitted from the substrate 5, but may have a top emission type configuration in which the CW excitation light is emitted from the first reflection layer R1 side.

The substrate 5 is, for example, an n-GaAs substrate 5. The n-GaAs substrate 5 absorbs light of a first wavelength λ1, which is the excitation wavelength of the excitation light source 2, at a certain rate, and hence is desirable to make the n-GaAs substrate 5 as thin as possible. In contrast, it is desirable to provide such a degree of thickness that can maintain mechanical strength at the time of a bonding process to be described later.

The active layer 7 performs surface emission at the first wavelength λ1. The cladding layers 6, 8 are non-doped AlGaAs cladding layers, for example. The first reflection layer R1 reflects the light of the first wavelength λ1. The fifth reflection layer R5 has a certain transmittance with respect to the light of the first wavelength λ1.

For the first reflection layer R1 and the fifth reflection layer R5, for example, a semiconductor distributed Bragg reflector (DBR) capable of performing electrical conduction is used. In the case of FIG. 1, the first reflection layer R1 is a p-DBR, and the fifth reflection layer R5 is an n-DBR. Each of the p-DBR and the n-DBR is a multilayer reflection layer in which a low refractive index layer and a high refractive index layer are alternately laminated. To the p-DBR and the n-DBR, corresponding dopants are added (e.g., carbon for the p-DBR and silicon for the n-DBR). More specifically, the p-DBR and the n-DBR are formed by Al_{z1}Ga_{1-z1}As/Al_{Z2}Ga_{1-z2}As (0≤z1≤z2≤1). In addition, z2=1 is desirably not satisfied for the sake of distinction from an oxide layer to be described later. The n-contact layer 33 is disposed between the fifth reflection layer R5 and the n-GaAs substrate 5.

A current is externally injected via the first reflection layer R1 and the fifth reflection layer R5, recombination and light emission occur in a quantum well in the active layer 7, and laser oscillation at the first wavelength λ1 is performed. A part of the pre-oxidation layer (e.g., AlAs layer) 31 on the cladding layer side of the first reflection layer R1 is removed and oxidized by dry etching or the like to be altered, and becomes a post-oxidation layer (e.g., Al₂O₃ layer) 32. This makes it possible to electrically and optically confine the light of the first wavelength.

The active layer 7 includes, for example, a multiple quantum well layer in which an Alₓ₁In_{y1}Ga_{1-x1-y1}As layer and an Alₓ₃In_{y3}Ga_{1-x3-y3}As layer are laminated. More specifically, the active layer 7 includes a quantum well layer and a barrier layer that are alternately laminated to have a compressive strain, and includes, for example, an Alₓ₁In_{y1}Ga_{1-x1-y1}As layer and an Alₓ₃In_{y3}Ga_{1-x3-y3}As layer. Furthermore, a multi-junction structure via a tunnel junction may be employed.

Each of the semiconductor layers R5, 6, 7, 8, R1 in the excitation light source 2 can be formed by using a crystal growth method such as a metal-organic chemical vapor deposition (MOCVD) method or a molecular beam epitaxy (MBE) method. Then, after the crystal growth, driving by current injection becomes possible after processes such as mesa etching for element separation, formation of an insulating film, and vapor deposition of an electrode film. Note that the laminated structure (laminated semiconductor layer) of the excitation light source 2 illustrated in FIG. 1 is an example, and the material of each semiconductor layer, the layer configuration, and the semiconductor process during manufacturing are not limited to the above description.

The solid-state laser medium 3 is bonded to the end face on the side opposite to the fifth reflection layer R5 of the n-GaAs substrate 5 of the excitation light source 2. Hereinafter, the end face on the excitation light source 2 side of the solid-state laser medium 3 is referred to as a first surface F1, and the end face on the saturable absorber 4 side of the solid-state laser medium 3 is referred to as a second surface F2. Furthermore, a laser pulse emission surface of the saturable absorber 4 is referred to as a third surface F3, and the end face on the solid-state laser medium 3 side of the excitation light source 2 is referred to as a fourth surface F4. Furthermore, the end face on the solid-state laser medium 3 side of the saturable absorber 4 is referred to as a fifth surface F5. Although illustrated separately for convenience in FIG. 1, the fourth surface F4 of the excitation light source 2 is bonded to the first surface F1 of the solid-state laser medium 3, and the second surface F2 of the solid-state laser medium 3 is bonded to the fifth surface F5 of the saturable absorber 4.

The laser element 1 of FIG. 1 includes a first resonator 11 and a second resonator 12. The first resonator 11 causes the light of the first wavelength λ1 to resonate between the first reflection layer R1 in the excitation light source 2 and a third reflection layer R3 in the solid-state laser medium 3. The second resonator 12 causes light of a second wavelength λ2 to resonate between a second reflection layer R2 in the solid-state laser medium 3 and a fourth reflection layer R4 in the saturable absorber 4. The conductivity type of the laminated semiconductor layer 2 may be opposite to that described above, or the substrate 5 may be a non-doped substrate.

The second resonator 12 is also referred to as a Q-switched solid-state laser resonator 12. A third reflection layer R3, which is a high reflection layer, is provided in the solid-state laser medium 3 so that the first resonator 11 can perform a stable resonance operation. In the normal excitation light source 2, a partially reflecting mirror for emitting the light of the first wavelength λ1 to the outside is disposed at a position of the third reflection layer R3 in FIG. 1. In contrast, in the laser element 1 of FIG. 1, the high reflection layer is used as the third reflection layer R3 in order to use the third reflection layer R3 for confining power of the excitation light of the first wavelength λ1 in the first resonator 11.

In this manner, three reflection layers (first reflection layer R1, fifth reflection layer R5, and third reflection layer R3) are provided inside the first resonator 11 including the excitation light source 2 and the solid-state laser medium 3. Therefore, the first resonator 11 has a coupled resonator (coupled cavity) structure.

The solid-state laser medium 3 is excited by confining the power of the excitation light of the first wavelength λ1 in the first resonator 11. Therefore, Q-switched laser pulse oscillation occurs in the second resonator 12. The second resonator 12 causes light of a second wavelength λ2 to resonate between a second reflection layer R2 in the solid-state laser medium 3 and a fourth reflection layer R4 in the saturable absorber 4. The second reflection layer R2 is a high reflection layer, whereas the fourth reflection layer R4 is a partial reflection layer. In FIG. 1, the fourth reflection layer R4 is provided on the end face of the saturable absorber 4, but the fourth reflection layer R4 may be disposed on a rear side of an optical axis with respect to the laser pulse emission surface of the saturable absorber 4. The rear side of the optical axis is in a light emission direction on the optical axis. That is, the fourth reflection layer R4 is not necessarily provided inside or on the surface of the saturable absorber 4. However, even in a case where the fourth reflection layer R4 is disposed on the front side of the optical axis with respect to the saturable absorber 4, it is necessary to cause the light of the second wavelength λ2 to resonate between the second reflection layer R2 and the fourth reflection layer R4.

The solid-state laser medium 3 contains, for example, ytterbium (Yb)-doped yttrium aluminum garnet (YAG) crystal Yb:YAG. In this case, the first wavelength λ1 of the first resonator 11 is 940 nm, and the second wavelength λ2 of the second resonator 12 is 1030 nm.

The solid-state laser medium 3 is not limited to Yb:YAG, and for example, at least any material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and YB:YAB can be used as the solid-state laser medium 3.

Furthermore, the solid-state laser medium 3 may be a four-level system solid-state laser medium 3 or a quasi-three-level system solid-state laser medium 3. However, since an appropriate excitation wavelength (first wavelength λ1) varies depending on each crystal, it is necessary to select the semiconductor material of the active layer 7 in the excitation light source 2 according to the material of the solid-state laser medium 3.

The saturable absorber 4 contains, for example, a chromium (Cr)-doped YAG (Cr:YAG) crystal. The saturable absorber 4 is a material in which the transmittance increases when the intensity of incident light exceeds a predetermined threshold. The excitation light of the first wavelength λ1 by the first resonator 11 increases the transmittance of the saturable absorber 4 to emit the laser pulse of the second wavelength λ2. This is referred to as a Q-switch. As the material of the saturable absorber 4, V:YAG can also be used. However, other types of saturable absorber 4 may also be used. Furthermore, the use of an active Q-switched element as the Q-switch is not prevented.

In FIG. 1, the excitation light source 2, the solid-state laser medium 3, and the saturable absorber 4 are separately illustrated, but they are bonded to be integrated by using a bonding process to form a laminated structure. Examples of the bonding process include surface activation bonding, atomic diffusion bonding, plasma activation bonding, and the like. Alternatively, other bonding (adhering) processes can be used.

To firmly bond the solid-state laser medium 3 to the excitation light source 2, it is necessary to flatten the surface of the n-GaAs substrate 5 in the excitation light source 2. Therefore, as described above, it is desirable that electrodes E1, E2 for injecting a current into the first reflection layer R1 and the fifth reflection layer R5 be arranged so as not to be exposed at least on the surface of the n-GaAs substrate 5. In the example in FIG. 1, the electrodes E1, E2 are arranged on the end face on the first reflection layer R1 side of the excitation light source 2. The electrode E1 is a p-electrode, and is electrically conducted with the first reflection layer R1. The electrode E2 is an n-electrode, and is formed by filling the side wall of the trench reaching from the first reflection layer R1 to the n-contact layer 33 with the conductive material 35 via the insulating film 34 and bringing the side wall into contact with the n-contact layer 33. Arranging the electrodes E1, E2 on the same end face of the excitation light source 2 as in FIG. 1 enables this end face to be soldered to a support substrate (not illustrated). Also, when a plurality of laser elements is arranged in an array, arranging the electrodes E1, E2 on the same end face enables this end face to be mounted on the support substrate. Note that the shapes and arranged positions of the electrodes E1, E2 illustrated in FIG. 1 are illustrative only.

In this manner, forming the laser element 1 of FIG. 1 into a laminated structure facilitates formation of a plurality of chips by dicing the laminated structure to separate after fabricating the same, or formation of a laser array in which a plurality of laser elements 1 is arranged in an array on one substrate.

In a case where the laser element 1 having the laminated structure is fabricated by the bonding process, arithmetic average roughness Ra of each surface layer needs to be about 1 nm or less, and is desirably 0.5 nm or less. Chemical mechanical polishing (CMP) is used to implement the surface layer having such arithmetic average roughness. Furthermore, in order to avoid an optical loss at the interface of each layer, a dielectric multilayer film may be disposed between the layers, and the layers may be bonded via the dielectric multilayer film. For example, the GaAs substrate 5 as the base substrate of the excitation light source 2 has a refractive index n of 3.2 with respect to a wavelength of 940 nm, which is higher than that of YAG (n:1.7) or a general dielectric multilayer film material. Therefore, when the solid-state laser medium 3 and the saturable absorber 4 are bonded to the excitation light source 2, it is necessary to prevent optical loss due to refractive index mismatch from occurring. Specifically, it is desirable to dispose an anti-reflection film (AR coating film or non-reflection coating film) that does not reflect the light of the first wavelength λ1 of the first resonator 11 between the excitation light source 2 and the solid-state laser medium 3. Furthermore, it is desirable to arrange an anti-reflection film (AR coating film or non-reflection coating film) also between the solid-state laser medium 3 and the saturable absorber 4.

Polishing is sometimes difficult depending on a bonding material, and for example, a material that is transparent with respect to the first wavelength λ1 and the second wavelength λ2, such as SiO₂, may be deposited as a base layer for bonding, and this SiO₂ layer may be polished to have arithmetic average roughness Ra of about 1 nm (preferably 0.5 nm or less) and used as an interface for bonding. Here, a material other than SiO₂ can be used as the base layer, and the material is not limited. Note that a non-reflection film may be provided between SiO₂ as the material of the base layer and a base material layer.

Examples of the dielectric multilayer film include a short-wave pass filter (SWPF), a long-wave pass filter (LWPF), a band pass filter (BPF), an anti-reflection (AR) protective film, and the like. It is desirable to arrange different types of dielectric multilayer films as necessary. A physical vapor deposition (PVD) method can be used as a film deposition method for the dielectric multilayer film, and specifically, a film deposition method such as vacuum vapor deposition, ion-assisted vapor deposition, and sputtering can be used. Which film deposition method is applied is not limited. Furthermore, any characteristic of the dielectric multilayer film can be selected, and for example, the second reflection layer R2 may be a short-wave pass filter, and the third reflection layer R3 may be a long-wave pass filter. Furthermore, applying the long-wave pass filter to the third reflection layer R3 makes it possible to prevent the first wavelength from entering the saturable absorber and to prevent malfunction of the Q-switch.

Note that the short-wave pass means that the light of the first wavelength λ1 is transmitted and the light of the second wavelength λ2 is reflected. Furthermore, the long-wave pass means that the light of the first wavelength λ1 is reflected and the light of the second wavelength λ2 is transmitted.

Furthermore, a polarizer having a photonic crystal structure that separates a ratio of P-polarized light and S-polarized light may be provided inside the second resonator 12. Furthermore, it is possible to provide a diffraction grating inside the second resonator 12 to convert the polarization state of the emitted laser pulse from random polarization to linear polarization.

### (Operation Principle of Laser Element 1)

Next, the operation of the laser element 1 of FIG. 1 will be described. By injecting a current into the active layer 7 via the electrode of the excitation light source 2, laser oscillation at the first wavelength λ1 occurs in the first resonator 11, and the solid-state laser medium 3 is excited. Since the saturable absorber 4 is bonded to the solid-state laser medium 3, in an initial stage when the laser oscillation at the first wavelength λ1 occurs, the spontaneous emission light from the solid-state laser medium 3 is absorbed by the saturable absorber 4, so that optical feedback by the fourth reflection layer R4 on the emission surface side of the saturable absorber 4 does not occur, and the Q-switched laser oscillation does not occur.

Thereafter, when the power of the excitation light of the first wavelength λ1 is accumulated in the solid-state laser medium 3, and the solid-state laser medium 3 comes into a sufficiently excited state, the output of the spontaneous emission light increase. When this exceeds a certain threshold, a light absorption rate in the saturable absorber 4 rapidly decreases, enabling the spontaneous emission light generated in the solid-state laser medium 3 to be transmitted through the saturable absorber 4. Therefore, the light of the first wavelength λ1 by the first resonator 11 is emitted from the solid-state laser medium 3, and the second resonator 12 causes the light of the second wavelength λ2 to resonate between the second reflection layer R2 and the fourth reflection layer R4. Therefore, the Q-switched laser oscillation occurs, and the Q-switched laser pulse is emitted toward a space (space on the right side in FIG. 1) via the fourth reflection layer R4.

A non-linear optical crystal for wavelength conversion can be disposed inside the second resonator 12. The wavelength of the laser pulse after the wavelength conversion can be changed depending on the type of the non-linear optical crystal. Examples of wavelength converting materials include non-linear optical crystals such as LiNbO₃, BBO, LBO, CLBO, BiBO, KTP, and SLT. Furthermore, a phase-matching material similar to these materials may be used as the wavelength converting material. Note that the type of the wavelength converting material is not limited. The second wavelength λ2 can be converted to another wavelength using the wavelength converting material.

The basic configuration and the operation principle for obtaining the Q-switched laser oscillation according to the present disclosure have been described above. However, the configuration of the laser element in FIG. 1 does not solve the problem of large diffraction loss due to the long resonator length of the first resonator 11 and limits on the laser output, as described at the beginning of the specification.

### (Measures for Inhibiting Diffraction Loss)

First, a cause of an increase in diffraction loss due to an increase in the resonator length of the first resonator 11 will be described. Here, the diffraction loss is caused by the presence of light emitted from the active layer 7, which is released to the outside of the first resonator 11 while resonating in the first resonator 11. if this released light can be kept in the resonator, the loss can be reduced. It is known that a resonator using a concave mirror as the reflection mirror can reduce diffraction loss more than one using a parallel flat mirror. However, a specific method for inhibiting diffraction loss of one resonator in a configuration of two resonators sharing a solid-state laser medium has not been proposed.

Hereinafter, a specific configuration of the laser element for inhibiting the diffraction loss of the first resonator 11 will be described. The laser element according to the present disclosure includes an optical element in addition to the basic structure illustrated in FIG. 1. The optical element is provided in the first resonator 11. The optical element has a function of condensing the light of the first wavelength in the optical axis direction. A plurality of configurations is conceivable as a specific configuration of the optical element, and thus, laser elements including optical elements having different configurations will be sequentially described below.

### (First Specific Example of Laser Element)

FIG. 2 is a cross-sectional view of a laser element 1 according to a first specific example. Similarly to FIG. 1, the laser element 1 of FIG. 2 has a configuration in which the excitation light source 2, the solid-state laser medium 3, and the saturable absorber 4 are integrally bonded. In the laser element 1 of FIG. 2, the electrodes E1, E2 illustrated in FIG. 1 are omitted.

The laser element 1 of FIG. 2 has an optical element 9. The optical element 9 of FIG. 2 includes a concave mirror 10. The concave mirror 10 of FIG. 2 is a first reflection layer R1 having a concave shape included in the excitation light source 2. The optical element 9 of FIG. 2 is obtained by processing the first reflection layer R1 of the excitation light source 2 into a concave shape. As described above, the first resonator 11 causes the light of the first wavelength λ1 to resonate between the first reflection layer R1 provided on the end face of the excitation light source 2 and the third reflection layer R3 provided on the end face of the solid-state laser medium 3. By forming the first reflection layer R1 into a concave shape, as indicated by a dashed line in FIG. 2, the light of the first wavelength λ1 reflected by the first reflection layer R1 travels in a direction in which the light is condensed in the optical axis direction of the first resonator 11. This reduces the ratio of light exiting from the first resonator 11 and can inhibit diffraction loss.

The laser element 1 of FIG. 2 is of a bottom emission type, in which an n-contact layer 33, a fifth reflection layer R5, a cladding layer 6, an active layer 7, a cladding layer 8, and a concave mirror formation layer 41 are sequentially laminated on a substrate 5, a surface of the concave mirror formation layer 41 is processed into a convex shape by dry etching or the like, and a concave mirror 10 including a multilayer film 42 formed by layering at least one of a semiconductor material, a metal material, or a dielectric material is disposed onto the formed convex surface by vapor deposition, sputtering, or the like. With the multilayer film 42 having a concave shape when viewed from the inside of the first resonator 11, it is referred to as a concave mirror 10 in the present specification. The material of the concave mirror formation layer 41 only needs to be a transparent material that transmits the light of the first wavelength λ1, and a specific material is not limited. The concave mirror 10 is the first reflection layer R1 that reflects the light of the first wavelength λ1 in a direction in which the light is condensed in the optical axis direction of the first resonator 11.

As described above, in the laser element 1 of FIG. 2, the first reflection layer R1 of FIG. 1 is processed into a convex shape, and the diffraction loss can be inhibited without adding a new member.

### (Second Specific Example of Laser Element 1)

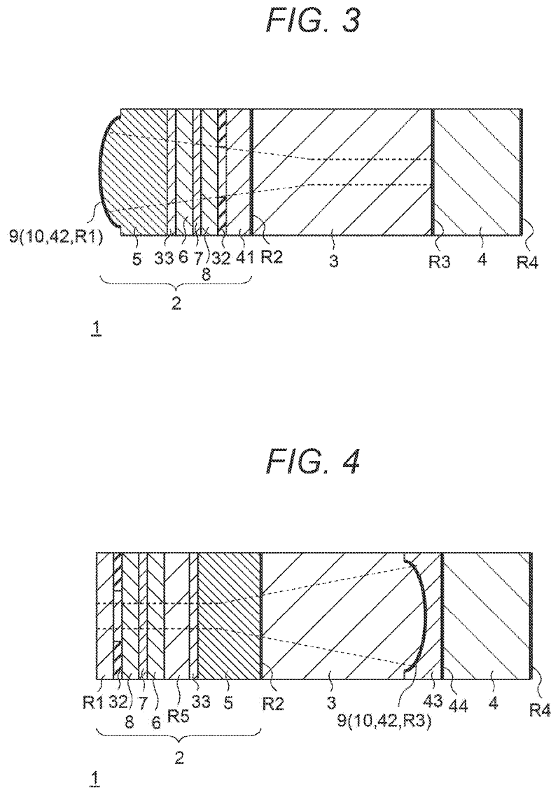

FIG. 3 is a cross-sectional view of a laser element 1 according to a second specific example. The laser element 1 of FIG. 3 also includes the optical element 9 including the concave mirror 10. The laser element 1 of FIG. 3 is of a top emission type. In the case of the top emission type, the substrate 5 of the excitation light source 2 is disposed on the side opposite to the solid-state laser medium 3, and the DBR on the substrate 5 side originally corresponds to the first reflection layer R1 that is a resonator mirror of the first resonator 11. In FIG. 3, the DBR on the substrate 5 side is removed, the surface of the substrate 5 is processed into a convex shape by dry etching or the like, and the multilayer film 42 for the excitation wavelength is formed on the convex surface by vapor deposition, sputtering, or the like, thereby forming the concave mirror 10 when viewed from the resonator. The concave mirror 10 is the first reflection layer R1 that reflects the light of the first wavelength λ1 in a direction in which the light is condensed in the optical axis direction.

As described above, in the laser element 1 of FIG. 3, the concave mirror 10 is formed by processing the end face of the top emission type substrate 5 into a convex shape, so that the diffraction loss can be inhibited without adding a new member.

### (Third Specific Example of Laser Element 1)

FIG. 4 is a cross-sectional view of a laser element 1 according to a third specific example. The laser element 1 of FIG. 4 includes the optical element 9 on the side of the solid-state laser medium 3 closer to the saturable absorber 4. The optical element 9 includes the concave mirror 10. The concave mirror 10 functions as the third reflection layer R3. The light of the first wavelength λ1 incident on the concave mirror 10 is reflected in a direction in which the light is condensed in the optical axis direction.

In the concave mirror 10 of FIG. 4, the surface of the solid-state laser medium 3 is processed into a convex shape by dry etching or the like, and the concave mirror 10 including the multilayer film 42 is disposed on the formed convex surface by vapor deposition, sputtering, or the like. The concave mirror 10 is the third reflection layer R3 that reflects the incident light of the first wavelength λ1 in a direction in which the light is condensed in the optical axis direction of the first resonator 11. Furthermore, the concave mirror 10 transmits the light of the second wavelength λ2.

When the end face of the solid-state laser medium 3 is processed into a convex shape, the saturable absorber 4 cannot be brought into surface contact as it is. Therefore, the transparent material layer 43 is formed on the concave mirror 10 disposed on the end face of the solid-state laser medium 3 to planarize the surface of the transparent material layer 43, and the saturable absorber 4 is bonded to the transparent material layer 43.

The transparent material layer 43 only needs to be a material that transmits the light of the second wavelength λ2, and a specific material is not limited. The transparent material layer 43 is formed to be thicker than the height of the concave mirror 10 by vapor deposition, sputtering, or the like, and is polished and planarized by chemical mechanical polishing (CMP) to a roughness (e.g., Ra is about 1 nm) at which the saturable absorber 4 can be bonded. As a result, the transparent material layer 43 and the saturable absorber 4 can be brought into stable surface contact with each other.

A non-reflection coating layer 44 may be disposed between the transparent material layer 43 and the saturable absorber 4. Disposing the non-reflection coating layer 44 eliminates the risk of the light of the second wavelength λ2 being reflected at the interface between the transparent material layer 43 and the saturable absorber 4.

### (Fourth Specific Example of Laser Element 1)

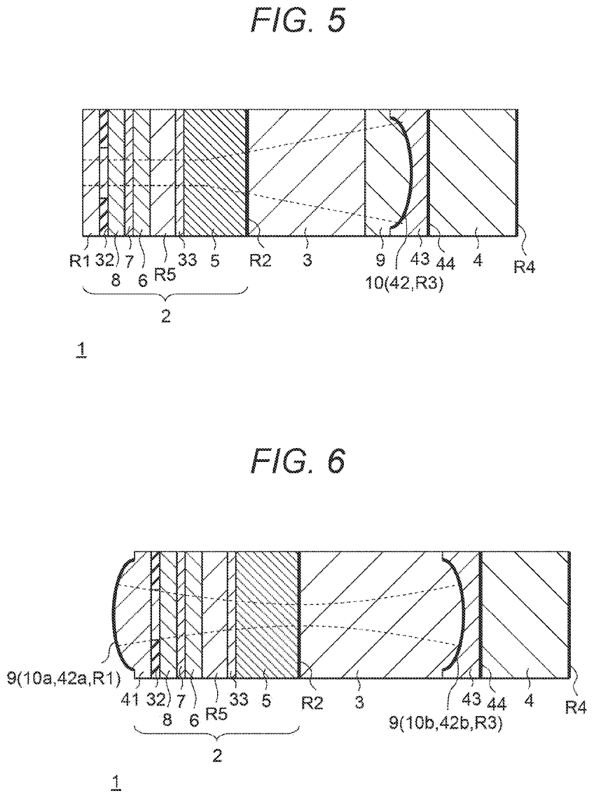

FIG. 5 is a cross-sectional view of a laser element 1 according to a fourth specific example. The laser element 1 of FIG. 5 includes the optical element 9 bonded to the end face of the solid-state laser medium 3. The optical element 9 is a member provided separately from the solid-state laser medium 3, and is a first transparent material layer. In FIG. 1, the third reflection layer R3 is disposed on the end face of the solid-state laser medium 3 on the side of the saturable absorber 4. However, in FIG. 5, the end face of the optical element 9 is processed into a convex shape, a concave mirror 10 including a multilayer film 42 is disposed on the convex surface, and the concave mirror 10 functions as the third reflection layer R3. As described above, the first transparent material layer, which is the base material of the optical element 9, has a flat surface for surface contact with the solid-state laser medium 3 and an end face having a convex shape.

The first transparent material layer that is the base material of the optical element 9 of FIG. 5 only needs to be a transparent material that transmits the light of the first wavelength λ1 and the light of the second wavelength λ2, and a specific material is not limited. The surface of the optical element 9 is processed into a convex shape by dry etching or the like. The concave mirror 10 including the multilayer film 42 disposed on the convex surface reflects the light of the first wavelength λ1 and transmits the light of the second wavelength λ2. Similarly to FIG. 4, a transparent material layer (also referred to as a second transparent material layer) 43 that transmits the light of the second wavelength λ2 is formed on the surface of the concave mirror 10 and planarized. Therefore, the saturable absorber 4 is stably brought into surface contact with the transparent material layer 43. Furthermore, the non-reflection coating layer 44 may be disposed at the interface between the transparent material layer 43 and the saturable absorber 4.

### (Fifth Specific Example of Laser Element 1)

FIG. 6 is a cross-sectional view of a laser element 1 according to a fifth specific example. The laser element 1 of FIG. 6 includes an optical element 9 including a concave mirror 10a corresponding to the concave mirror 10 of FIG. 2 and a concave mirror 10b corresponding to the concave mirror 10 of FIG. 4. The concave mirror 10a has a multilayer film 42a disposed along the concave surface, and the concave mirror 10b has a multilayer film 42b arranged along the concave surface.

Both the concave mirror 10 of FIG. 2 and the concave mirror 10 of FIG. 4 reflect the light of the first wavelength λ1 in a direction in which the incident light is condensed in the optical axis direction of the first resonator 11. Therefore, by providing both the concave mirror 10 of FIG. 2 and the concave mirror 10 of FIG. 4, the diffraction loss can be further inhibited, and the light intensity of the laser output can be further improved.

### (Sixth Specific Example of Laser Element 1)

In the laser elements 1 according to the first to fifth specific examples described above, at least one of the first reflection layer R1 or the third reflection layer R3 of the first resonator 11 is formed as the concave mirror 10, so that the light of the first wavelength λ1 is reflected in a direction in which the light is condensed in the optical axis direction to inhibit the diffraction loss. On the other hand, in laser elements 1 according to seventh to ninth specific examples to be described below, the optical element 9 including the light refracting member is provided inside the excitation light source 2 and refracts the light of the first wavelength λ1 in a direction in which the light is condensed.

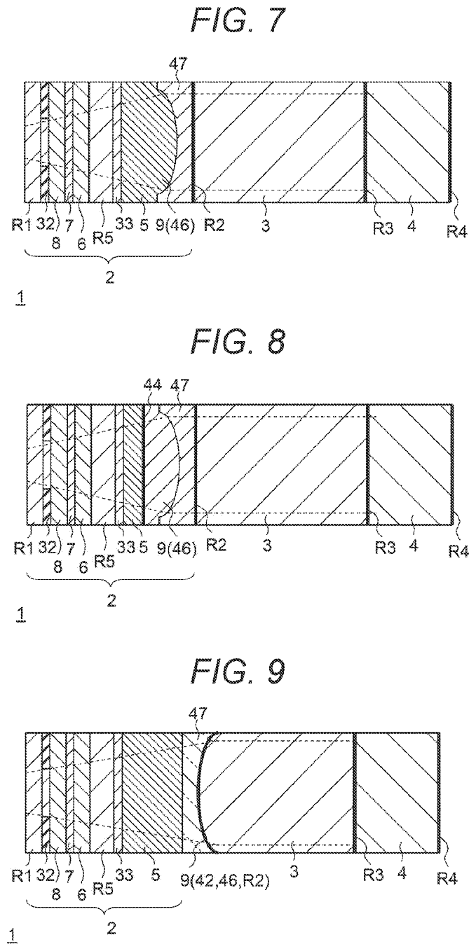

FIG. 7 is a cross-sectional view of a laser element 1 according to a sixth specific example. The laser element 1 of FIG. 7 is provided with an optical element 9 including a light refracting member 46 inside the excitation light source 2. The light refracting member 46 of FIG. 7 is formed by processing the surface of the substrate in the excitation light source 2 into a convex shape by dry etching or the like. The light refracting member 46 functions as a convex lens, refracts and emits the light of the first wavelength λ1 incident from the first reflection surface side in a direction of parallelization, and refracts and emits the light of the first wavelength λ1 incident from the third reflection surface side in a direction in which the light is condensed in the optical axis direction.

When the end face of the excitation light source 2 on the solid-state laser medium 3 side is a convex surface, the end face cannot be brought into surface contact with the solid-state laser medium 3. Therefore, a transparent material layer 47 having a refractive index smaller than that of the substrate in the excitation light source 2 is formed on the convex surface, planarized by CMP or the like, and bonded to the solid-state laser medium 3. The transparent material layer 47 is a material having a refractive index smaller than that of the material of the substrate of the excitation light source 2, and needs to be formed thick enough to flatten the convex surface.

Although FIG. 7 illustrates the bottom emission type laser element 1, in the case of the top emission type, a DBR, which is the material of the first reflection layer R1 of FIG. 7, is disposed in the vicinity of the second reflection layer R2. Since the DBR cannot be processed into a convex shape, the substrate 5 bonded to the DBR is processed into a convex shape to form the light refracting member 46.

### (Seventh Specific Example of Laser Element 1)

FIG. 8 is a cross-sectional view of a laser element 1 according to a seventh specific example. In the laser element 1 of FIG. 8, the optical element 9 including the light refracting member 46 is disposed between the excitation light source 2 and the solid-state laser medium 3. The light refracting member 46 functions as a convex lens. In FIG. 7, the light refracting member 46 having a convex shape is formed by processing the substrate of the excitation light source 2, whereas in FIG. 8, the light refracting member 46 having a convex shape is disposed separately from the excitation light source 2.

The light refracting member 46 of FIG. 8 is formed by forming a first transparent material layer 47 having a thickness, with which a convex surface can be formed on the end face of the excitation light source 2, and processing the first transparent material layer 47 into a convex shape by dry etching or the like. In FIG. 8 as well, the solid-state laser medium 3 cannot be brought into surface contact with the convex surface as it is, and thus, a second transparent material layer 47 having a refractive index smaller than that of the first transparent material layer 47 is formed on the convex surface by vapor deposition, sputtering, or the like and planarized by CMP, and then the solid-state laser medium 3 is bonded. Note that the non-reflection coating layer 44 may be disposed between the light refracting member 46 and the substrate 5 of the excitation light source 2.

### (Eighth Specific Example of Laser Element 1)

FIG. 9 is a cross-sectional view of a laser element 1 according to an eighth specific example. In the laser element 1 of FIG. 9, the end face of the solid-state laser medium 3 on the excitation light source 2 side is processed into a convex shape by dry etching or the like to form the multilayer film 42 on the convex surface, thereby forming the light refracting member 46. The multilayer film 42 of the light refracting member 46 functions as the second reflection layer R2 that transmits the light of the first wavelength λ1 and reflects the light of the second wavelength λ2. Hence the light refracting member 46 functions as a convex lens for the light of the first wavelength λ1. Since the multilayer film 42 of the light refracting member 46 has a convex shape, the transparent material layer 47 that transmits the light of the first wavelength λ1 is formed on the multilayer film 42 and planarized by CMP or the like. As a result, the transparent material layer 47 and the excitation light source 2 can be firmly bonded.

Each of the sixth to eighth specific examples has illustrated an example in which the optical element 9 is the light refracting member 46. However, even the optical element 9 with a fine periodic structure can condense the light of the first wavelength λ1 in the optical axis direction. The fine periodic structure is, for example, a Fresnel lens, a meta-lens, a photonic crystal lens, or the like. Furthermore, the optical element 9 with a structure having a refractive index distribution in a plane intersecting the optical axis can also condense the light of the first wavelength λ1 in the optical axis direction. The structure having the refractive index distribution is, for example, a GRIN lens or a base material modified by irradiating a base material such as glass with laser light.

### (Ninth Specific Example of Laser Element 1)

Since the excitation light source 2 is a form of the VCSEL as described above, it is also possible to arrange laser light sources in an array in a one-dimensional or two-dimensional direction.

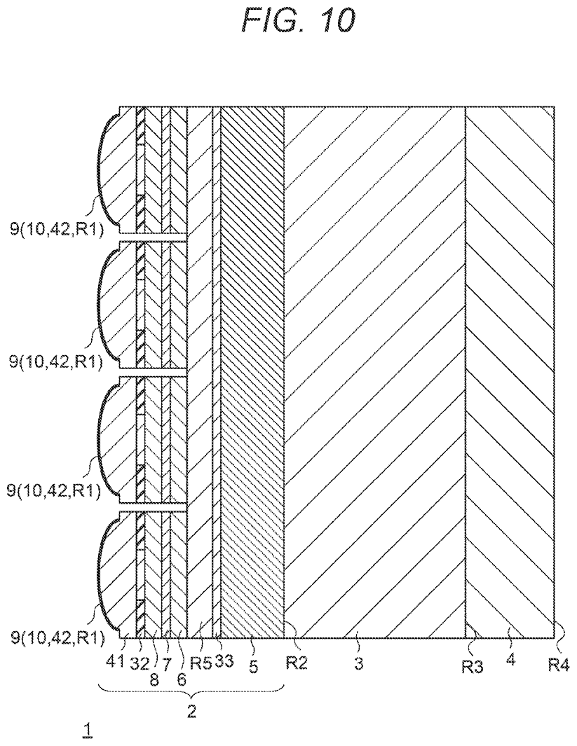

FIG. 10 is a cross-sectional view of a laser element 1 according to a ninth specific example. In the excitation light source 2 of FIG. 10, a part of the semiconductor layer including the active layer 7 is divided into a plurality of divided regions, and each of the divided regions has a first resonator 11 and a second resonator 12. This forms a laser array. In FIG. 10, by providing the optical element 9 described above for each divided region, the light of the first wavelength λ1 in the first resonator 11 can be condensed in the optical axis direction for each divided region. Therefore, the diffraction loss can be inhibited for each divided region. Similarly to FIG. 2, the laser element 1 of FIG. 10 illustrates an example in which the first reflection surface R1 in each divided region is the concave mirror 10. The optical element 9 is not limited to the first specific example, and may have a mode similar to any of the second to eighth specific examples described above.

### (Other Modifications of Laser Element 1)

In the laser element 1 according to the present disclosure, since the excitation light source 2 and the solid-state laser medium 3 are bonded to each other, thermal interference may occur between the excitation light source 2 and the solid-state laser medium 3. When thermal interference occurs, conversion efficiency from the first wavelength λ1 to the second wavelength λ2 decreases in the solid-state laser medium 3. Furthermore, the temperature inside the excitation light source 2 rises, and the I-L characteristic (light emission efficiency) of the excitation light source 2 decreases. Moreover, the temperature of the active layer 7 in the excitation light source 2 rises, and long-term reliability (mean time to failure (MTTF)) deteriorates.

To prevent thermal interference between the excitation light source 2 and the solid-state laser medium 3, it is desirable to provide a heat exhaust member between the excitation light source 2 and the solid-state laser medium 3. The heat exhaust member is, for example, sapphire or diamond having a refractive index and a linear expansion coefficient equivalent to those of YAG and having a thermal conductivity higher than that of YAG. For example, by laminating a sapphire layer between the excitation light source 2 and the solid-state laser medium 3, the problems described above can be avoided without impairing the advantages of miniaturization and integration.

Furthermore, in the laser element 1 according to the present disclosure, the resonator length of the second resonator 12 can be reduced by integrating the laser element 1 in a small size, and hence the pulse width of the laser pulse emitted from the laser element 1 is further reduced. The shorter the pulse width of the laser pulse, the higher the peak power, so that the optical damage is more likely to occur than in the conventional case.

The optical damage occurs not only inside the second resonator 12 that generates the Q-switched laser pulse but also inside the excitation light source 2 (excitation light source 2) because return light is generated on the excitation light source 2 side. Especially, since the semiconductor layer 2 with the laminated structure forming the excitation light source 2 is formed using a material with a small band gap, the optical damage caused by multiphoton absorption by short-pulse laser light is likely to occur. Therefore, it is desirable to arrange a plurality of short-wave pass filters (SWPFs) at a plurality of interfaces between the excitation light source 2 and the solid-state laser medium 3 while reducing the resonator length.

The laser element 1 and the laser device according to the present disclosure adopt a laminated structure in which the optical axis of the excitation light and the optical axis of the laser light are coaxial. In the laser element 1 and the laser device according to the present disclosure, it is not necessary to perform alignment at a complicated position and angle, and the structure is simplified. This facilitates a reduction in the sizes of the laser element 1 and the laser device. Furthermore, it is possible to simultaneously form a plurality of laser elements 1 according to the present disclosure by laminating or bonding a plurality of materials on the same semiconductor substrate. Only the separation of each laser element 1 through dicing in the subsequent process is required, enabling the mass production of high-performance laser elements 1 at a low cost.

### (Manufacturing Method for Laser Element 1 of Present Disclosure)

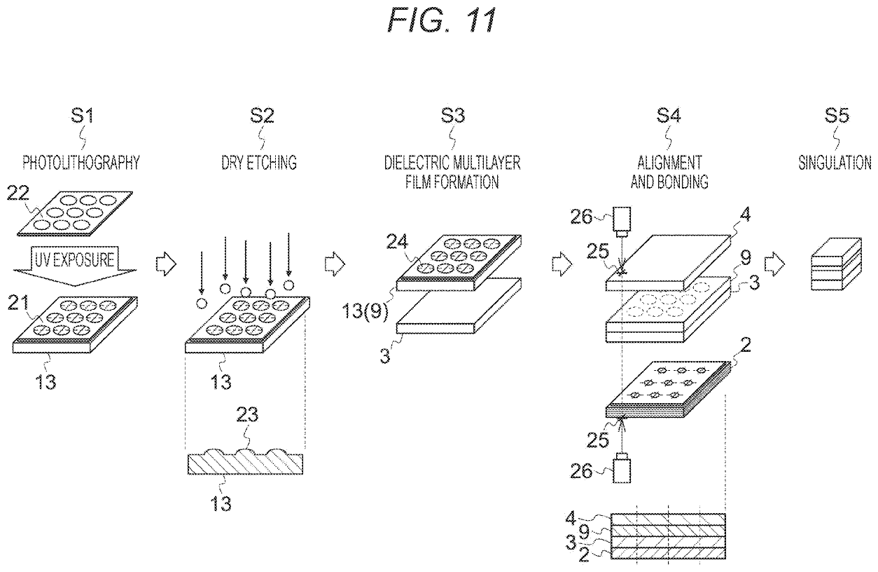

FIG. 11 is a view schematically illustrating the manufacturing process of the laser element 1 of the present disclosure. FIG. 11 illustrates the manufacturing process of forming the laser element 1 having the structure in FIG. 5. First, as illustrated in step S1 of FIG. 11, a resist film 21 is applied onto a base material 13 for the optical element 9 bonded to the end face of the solid-state laser medium on the side of the saturable absorber 4, a photomask 22 is disposed on the resist film 21, and ultraviolet (UV) exposure is performed.

Next, as illustrated at step S2, the exposed portion and the resist film 21 are removed by dry etching or the like to form a plurality of protrusions 23 on the third surface of the saturable absorber 4. Next, as described in step S3, the multilayer film 24 is formed on the plurality of protrusions 23 by vapor deposition, sputtering, or the like, and the concave mirror 10 is formed on the surface of the optical element 9.

Next, as described in step S4, the semiconductor layer 2 for the excitation light source 2, the solid-state laser medium 3, the optical element 9 processed in step S2, and the saturable absorber 4 are arranged and aligned in the vertical direction. At that time, the semiconductor layer 2, the solid-state laser medium 3, the optical element 9, and the saturable absorber 4 are aligned and bonded so that the alignment marks 25 are vertically overlapped by, for example, photographing the alignment marks 25 provided at specific locations of the semiconductor layer 2, the solid-state laser medium 3, the optical element 9, and the saturable absorber 4 with the camera 26. Next, as shown in step S5, singulation is performed by dicing into individual laser elements 1.

### (Effect of Laser Element 1 of Present Disclosure)

As described above, in the laser element 1 according to the present disclosure, the optical element 9 that condenses the light of the first wavelength λ1 in the optical axis direction is provided in the first resonator 11, making it possible to reduce the ratio of the light of the first wavelength λ1 leaking from the first resonator 11 to the outside and inhibit the diffraction loss. Inhibiting the diffraction loss can enhance the light intensity of the laser light emitted from the laser element 1.

In the laser element 1 according to the present disclosure, the first resonator 11 and the second resonator 12 share the solid-state laser medium 3. Furthermore, the light transmission surfaces of all the optical components including the excitation light source 2, the solid-state laser medium 3, and the saturable absorber 4 in the laser element 1 are bonded and fixed by the bonding process. Moreover, the optical element 9 described above is provided inside the first resonator 11. The optical element 9 is formed by, for example, processing the end face of the excitation light source 2 or the solid-state laser medium 3 into a convex shape, and can be formed without adding a new member. According to the laser element 1 of the present disclosure, the reliability and mass productivity of the laser element 1 are improved, and the laser element 1 having high performance at low cost can be obtained.

According to the present disclosure, the solid-state laser medium 3 is bonded to the excitation light source 2, the solid-state laser medium 3 is excited by a standing wave in the excitation light source 2. By designing a resonator that confines the excitation light inside the first resonator 11, even in a case where the solid-state laser medium 3 has such a thickness that a single passage of the laser light in the first resonator 11 does not lead to full absorption, the laser light can be reciprocated many times, and finally the excitation light can be sufficiently absorbed by the solid-state laser medium 3. This makes it possible to perform Q-switched laser oscillation with a shorter pulse without reducing excitation efficiency.

In the conventional Q-switched solid-state laser, the solid-state laser medium 3 is excited by a traveling wave, and how to excite is greatly different from that of the laser element 1 according to the present disclosure. In the laser element 1 according to the present disclosure, it is possible to solve the above-described trade-off that the amount of excitation light absorbed decreases when the solid-state laser medium 3 is reduced.

Furthermore, according to the laser element 1 of the present disclosure, it is possible to inhibit short-term and long-term fluctuations in laser output due to mechanical positional deviation by directly bonding the light transmission surface of each optical component. Furthermore, since all the optical components can be bonded and then diced into individual laser light sources, mass productivity can be improved.

Conventionally, the excitation light source 2 and the second resonator 12 perform five-axis optical adjustment (X, Y, Z, θ, φ) with respect to the optical axis, eccentricity, and focus using a plurality of lenses including a collimator lens and a condenser lens. Furthermore, when it is attempted to add an optical element 9 having a beam divergence function (negative refractive power) to the second resonator 12, it becomes more difficult to accurately adjust the position of the optical element 9.

However, in the laser element 1 according to the present disclosure, in order to align the light emission point of the excitation light source 2 and the center position of the concave mirror 10 of the optical element 9 without using the plurality of lenses, which are the collimator lens and the condenser lens, bonding is performed by using the alignment mark 25 and the like, so that it is not necessary to adjust the focus position accuracy in the thickness (Z-axis) direction or the inclination in the θ and φ directions. Therefore, the laser element 1 of the present disclosure makes it possible to inhibit the short-term and long-term fluctuations in laser output, facilitates optical adjustment due to the oscillation light obtained from the excitation light source 2, and implements the light source with improved mass productivity.

Furthermore, the laser element 1 according to the present disclosure adopts a laminated structure in which the optical axis of the first resonator 11 and the optical axis of the second resonator 12 are integrated so as to be coaxial. In the laser element 1 according to the present disclosure, it is not necessary to perform complicated position and angle alignment, and the structure is simplified. This facilitates the size reduction of the laser element 1.

Furthermore, a plurality of laser elements 1 according to the present disclosure can be simultaneously formed by laminating or bonding a plurality of materials on the same semiconductor substrate 5. By dicing in a post-process after the plurality of laser elements 1 is simultaneously formed to separate each laser element 1, it is possible to mass-produce high-performance laser elements 1 at a low cost. Furthermore, according to the laser element 1 of the present disclosure, it is possible to easily fabricate the laser array 18 in which the plurality of laser elements 1 is two-dimensionally arranged on one substrate.

Furthermore, in the laser element 1 according to the present disclosure, a repetition frequency of the laser pulse can be adjusted depending on the type of the solid-state laser medium 3. Especially, the laser element 1 according to the present disclosure has a high gain density, thus enabling an increase in the repetition frequency of the laser pulse. Furthermore, in the laser element 1 according to the present disclosure, the resonator length can be changed only by adjusting the thicknesses of the solid-state laser medium 3, the Q-switch (the saturable absorber 4), and the wavelength converting material (the non-linear optical crystal). That is, since the pulse time width of the laser pulse can be changed depending on the thickness of the material, the characteristic of the laser pulse can be easily adjusted. Especially, reducing the pulse time width of the laser pulse can increase processing accuracy in the field of fine processing.

Moreover, arraying the laser elements 1 according to the present disclosure in a one-dimensional array or a two-dimensional array makes it possible to obtain a laser device that achieves both high processing accuracy and high output energy. Furthermore, the laser element 1 according to the present disclosure can be applied to other fields such as highly efficient wavelength conversion technology, medical equipment, and ranging.

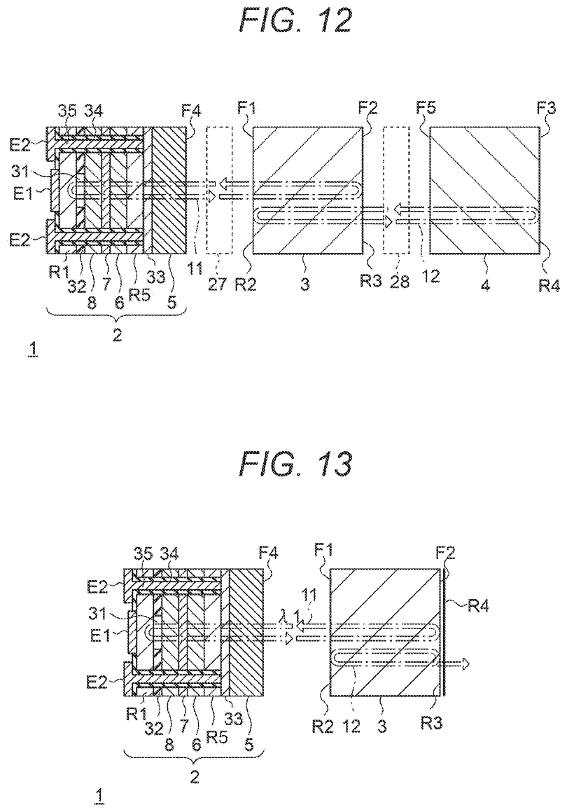

The laser element 1 of FIG. 1 has illustrated an example in which the excitation light source 2, the solid-state laser medium 3, and the saturable absorber 4 are integrally bonded. However, as illustrated in FIG. 12, a first transparent medium 27 that transmits the light of the first wavelength λ1 may be disposed between the excitation light source 2 and the solid-state laser medium 3.

Furthermore, as illustrated in FIG. 12, a second transparent medium 28 that transmits the light of the second wavelength λ2 may be disposed between the solid-state laser medium 3 and the saturable absorber 4. Note that only one of the first transparent medium 27 and the second transparent medium 28 may be disposed.

In this manner, the excitation light source 2, the solid-state laser medium 3, and the saturable absorber 4 are not necessarily integrally bonded.

### (Laser Element 1 not Including Saturable Absorber 4)

FIG. 1 has illustrated an example in which the laser element 1 includes the saturable absorber 4 and emits the short-pulse pulsed laser light. However, diffraction loss may also occur in the laser element 1 that does not include the saturable absorber 4 and emits the CW laser light.

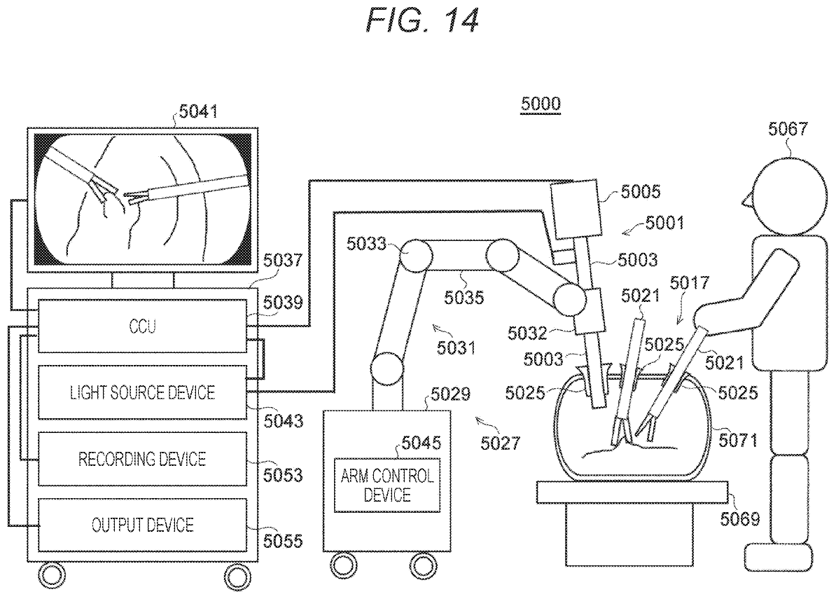

FIG. 13 is a diagram illustrating a basic configuration of the laser element 1 not including the saturable absorber 4. The laser element 1 of FIG. 13 has a configuration in which the saturable absorber 4 is omitted from FIG. 1. Similarly to FIG. 1, the first resonator 11 causes the light of the first wavelength λ1 to resonate between the first reflection layer R1 in the excitation light source 2 and the third reflection layer R3 in the solid-state laser medium 3. On the other hand, unlike FIG. 1, the second resonator 12 causes the light of the second wavelength λ2 to resonate between the second reflection layer R2 and the fourth reflection layer R4 in the solid-state laser medium 3. The fourth reflection layer R4 is disposed on the second surface of the solid-state laser medium 3 or on the rear side of the optical axis with respect to the second surface.

FIG. 13 illustrates an example in which the third reflection layer R3 and the fourth reflection layer R4 are separately provided along the second surface F2 of the solid-state laser medium 3. In a case where the fourth reflection layer R4 is disposed on the rear side of the optical axis with respect to the third reflection layer R3 as in FIG. 13, the third reflection layer R3 needs to have a characteristic of transmitting the light of the second wavelength λ2.

The third reflection layer R3 is a high reflection layer, whereas the fourth reflection layer R4 is a partial reflection layer. Therefore, the power of the excitation light of the first wavelength λ1 is confined in the solid-state laser medium 3, and when the solid-state laser medium 3 comes into a sufficiently excited state and the output of the spontaneous emission light increases, the light of the second wavelength λ2 is transmitted through the fourth reflection layer R4 to be emitted from the laser element 1.

Note that the third reflection layer R3 and the fourth reflection layer R4 may be integrated into one reflection layer. In this case, the integrated reflection layer reflects the light of the first wavelength λ1 and reflects the light of the second wavelength λ2. By providing the optical element 9 illustrated in any one of FIGS. 2 to 9 in the laser element 1 of FIG. 13, the diffraction loss can be inhibited.

As described above, even in the laser element 1 not including the saturable absorber 4, the light of the first wavelength λ1 in the first resonator 11 can be condensed in the optical axis direction by providing the optical element 9, and the diffraction loss can be inhibited.

### Application Examples

The technology according to the present disclosure can be widely applied to a medical imaging system (hereinafter, also referred to as an electronic device), a ranging system such as a light detection and ranging (LiDAR) device, a light source for a laser processing device, and the like. The medical imaging system is a medical system using an imaging technology, and is, for example, an endoscope system or a microscope system.

### [Endoscope System]

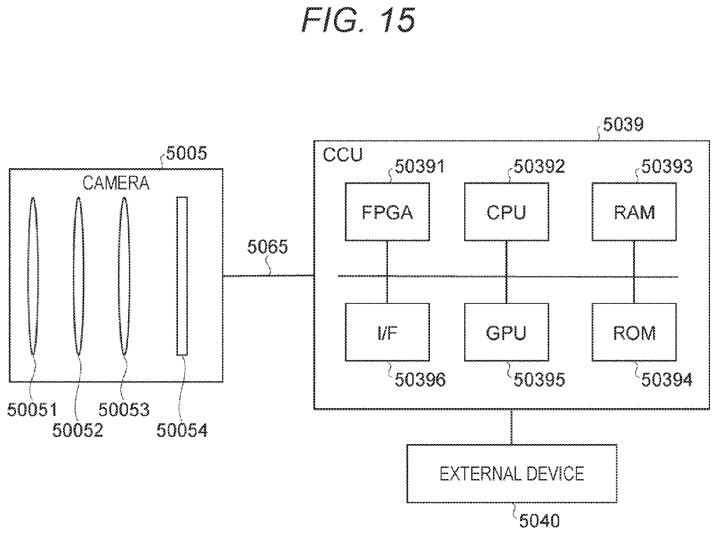

An example of an endoscope system will be described with reference to FIGS. 14 and 15. FIG. 14 is a diagram illustrating an example of a schematic configuration of an endoscope system 5000 to which the technology according to the present disclosure can be applied. FIG. 15 is a diagram illustrating an example of a configuration of an endoscope 5001 and a camera control unit (CCU) 5039. FIG. 14 illustrates a state in which an operator (e.g., doctor) 5067, who is a surgery participant, is performing surgery on a patient 5071 on a patient bed 5069 using the endoscope system 5000. As illustrated in FIG. 14, the endoscope system 5000 includes the endoscope 5001 that is a medical imaging device, the CCU 5039, a light source device 5043, a recording device 5053, an output device 5055, and a support device 5027 that supports the endoscope 5001.

In endoscopic surgery, insertion assisting tools called trocars 5025 are punctured into the patient 5071. Then, a scope 5003 connected to the endoscope 5001 and surgical tools 5021 are inserted into a body of the patient 5071 through the trocars 5025. The surgical tools 5021 include: an energy device such as an electric scalpel; and forceps, for example.

A surgical image that is a medical image in which the inside of the body of the patient 5071 is captured by the endoscope 5001 is displayed on a display device 5041. The operator 5067 performs a procedure on a surgical target using the surgical tools 5021 while viewing the surgical image displayed on the display device 5041. The medical image is not limited to the surgical image, and may be a diagnostic image captured during diagnosis.

### [Endoscope]

The endoscope 5001 is an imaging unit for capturing the inside of the body of the patient 5071, and is, for example, as illustrated in FIG. 15, a camera 5005 including a condensing optical system 50051 for condensing incident light, a zooming optical system 50052 capable of optical zooming by changing a focal length of the imaging unit, a focusing optical system 50053 capable of focus adjustment by changing the focal length of the imaging unit, and a light receiving sensor 50054. The endoscope 5001 condenses the light through the connected scope 5003 on the light receiving sensor 50054 to generate a pixel signal, and outputs the pixel signal through a transmission system to the CCU 5039. The scope 5003 is an insertion part that includes an objective lens at a distal end and guides the light from the connected light source device 5043 into the body of the patient 5071. The scope 5003 is, for example, a rigid scope for a rigid endoscope and a flexible scope for a flexible endoscope. The scope 5003 may be a direct viewing scope or an oblique viewing scope. The pixel signal only needs to be a signal based on a signal output from a pixel, and is, for example, a raw signal or an image signal. The transmission system connecting the endoscope 5001 to the CCU 5039 may include a memory, and the memory may store parameters related to the endoscope 5001 and the CCU 5039. The memory may be disposed at a connection portion of the transmission system or on a cable. For example, the memory of the transmission system may store the parameters before shipment of the endoscope 5001 or the parameters changed when current is applied, and an operation of the endoscope may be changed based on the parameters read from the memory. A set of the camera and the transmission system may be referred to as an endoscope. The light receiving sensor 50054 is a sensor for converting the received light into the pixel signal, and is, for example, a complementary metal-oxide-semiconductor (CMOS) imaging sensor. The light receiving sensor 50054 is preferably an imaging sensor having a Bayer array capable of color imaging. The light receiving sensor 50054 is also preferably an imaging sensor having a number of pixels corresponding to a resolution of, for example, 4K (3840 horizontal pixels×2160 vertical pixels), 8K (7680 horizontal pixels×4320 vertical pixels), or square 4K (3840 or more horizontal pixels×3840 or more vertical pixels). The light receiving sensor 50054 may be one sensor chip, or a plurality of sensor chips. For example, a prism may be provided to separate the incident light into predetermined wavelength bands, and the wavelength bands may be imaged by different light receiving sensors. A plurality of light receiving sensors may be provided for stereoscopic viewing. The light receiving sensor 50054 may be a sensor having a chip structure including an arithmetic processing circuit for image processing, or may be a sensor for time of flight (ToF). The transmission system is, for example, an optical fiber cable system or a wireless transmission system. The wireless transmission only needs to be capable of transmitting the pixel signal generated by the endoscope 5001, and, for example, the endoscope 5001 may be wirelessly connected to the CCU 5039, or the endoscope 5001 may be connected to the CCU 5039 via a base station in an operating room. At this time, the endoscope 5001 may transmit not only the pixel signal, but also simultaneously information (for example, a processing priority of the pixel signal and/or a synchronization signal) related to the pixel signal. In the endoscope, the scope may be integrated with the camera, and the light receiving sensor may be provided at the distal end of the scope.

### [CCU (Camera Control Unit)]

The CCU 5039 is a control device that integrally controls the connected endoscope 5001 and light source device 5043, and is, for example, an information processing device including an FPGA 50391, a CPU 50392, a RAM 50393, a ROM 50394, a GPU 50395, and an I/F 50396 as illustrated in FIG. 15. The CCU 5039 may control the display device 5041, the recording device 5053, and the output device 5055 connected to the CCU 5039 in an integrated manner. The CCU 5039 controls, for example, irradiation timing, irradiation intensity, and a type of an irradiation light source of the light source device 5043. The CCU 5039 also performs image processing, such as development processing (for example, demosaic processing) and correction processing, on the pixel signal output from the endoscope 5001, and outputs the processed image signal (for example, an image) to an external device such as the display device 5041. The CCU 5039 also transmits a control signal to the endoscope 5001 to control driving of the endoscope 5001. The control signal is information on an imaging condition such as a magnification or the focal length of the imaging section. The CCU 5039 may have a function to down-convert the image, and may be configured to be capable of simultaneously outputting a higher-resolution (for example, 4K) image to the display device 5041 and a lower-resolution (for example, high-definition (HD)) image to the recording device 5053.

The CCU 5039 may be connected to external equipment (such as a recording device, a display device, an output device, and a support device) via an IP converter for converting the signal into a predetermined communication protocol (such as the Internet Protocol (IP)). The connection between the IP converter and the external equipment may be established using a wired network, or a part or the whole of the network may be established using a wireless network. For example, the IP converter on the CCU 5039 side may have a wireless communication function, and may transmit the received image to an IP switcher or an output side IP converter via a wireless communication network, such as the fifth-generation mobile communication system (5G) or the sixth-generation mobile communication system (6G).

### [Light Source Device]

The light source device 5043 is a device capable of emitting the light having predetermined wavelength bands, and includes, for example, a plurality of light sources and a light source optical system for guiding the light of the light sources. The light sources are, for example, xenon lamps, light-emitting diode (LED) light sources, or laser diode (LD) light sources. The light source device 5043 includes, for example, the LED light sources corresponding to three respective primary colors of red (R), green (G), and blue (B), and controls output intensity and output timing of each of the light sources to emit white light. The light source device 5043 may include a light source capable of emitting special light used for special light observation, in addition to the light sources for emitting normal light for normal light observation. The special light is light having a predetermined wavelength band different from that of the normal light being light for the normal light observation, and is, for example, near-infrared light (light having a wavelength of 760 nm or longer), infrared light, blue light, or ultraviolet light. The normal light is, for example, the white light or green light. In narrow band imaging that is a kind of special light observation, blue light and green light are alternately emitted, and thus the narrow band imaging can image a predetermined tissue such as a blood vessel in a mucosal surface at high contrast using wavelength dependence of light absorption in the tissue of the body. In fluorescence observation that is a kind of special light observation, excitation light is emitted for exciting an agent injected into the tissue of the body, and fluorescence emitted by the tissue of the body or the agent as a label is received to obtain a fluorescent image, and thus the fluorescence observation can facilitate the operator to view, for example, the tissue of the body that is difficult to be viewed by the operator with the normal light. For example, in fluorescence observation using the infrared light, the infrared light having an excitation wavelength band is emitted to an agent, such as indocyanine green (ICG), injected into the tissue of the body, and the fluorescence light from the agent is received, whereby the fluorescence observation can facilitate viewing of a structure and an affected part of the tissue of the body. In the fluorescence observation, an agent (such as 5-aminolevulinic acid (5-ALA)) may be used that emits fluorescence in a red wavelength band by being excited by the special light in a blue wavelength band. The type of the irradiation light of the light source device 5043 is set by control of the CCU 5039. The CCU 5039 may have a mode of controlling the light source device 5043 and the endoscope 5001 to alternately perform the normal light observation and the special light observation. At this time, information based on a pixel signal obtained by the special light observation is preferably superimposed on a pixel signal obtained by the normal light observation. The special light observation may be an infrared light observation to observe a site inside the surface of an organ and a multi-spectrum observation utilizing hyperspectral spectroscopy. A photodynamic therapy may be incorporated.

### [Recording Device]

The recording device 5053 is a device for recording the pixel signal (for example, an image) acquired from the CCU 5039, and is, for example, a recorder. The recording device 5053 records an image acquired from the CCU 5039 in a hard disk drive (HDD), a Super Density Disc (SDD), and/or an optical disc. The recording device 5053 may be connected to a network in a hospital to be accessible from equipment outside the operating room. The recording device 5053 may have a down-convert function or an up-convert function.

### [Display Device]

The display device 5041 is a device capable of displaying the image, and is, for example, a display monitor. The display device 5041 displays a display image based on the pixel signal acquired from the CCU 5039. The display device 5041 may include a camera and a microphone to function as an input device that allows instruction input through gaze recognition, voice recognition, and gesture.

### [Output Device]

The output device 5055 is a device for outputting the information acquired from the CCU 5039, and is, for example, a printer. The output device 5055 prints, for example, a print image based on the pixel signal acquired from the CCU 5039 on a sheet of paper.

### [Support Device]

The support device 5027 is an articulated arm including a base 5029 including an arm control device 5045, an arm 5031 extending from the base 5029, and a holding part 5032 mounted at a distal end of the arm 5031. The arm control device 5045 includes a processor such as a CPU, and operates according to a predetermined computer program to control driving of the arm 5031. The support device 5027 uses the arm control device 5045 to control parameters including, for example, lengths of links 5035 constituting the arm 5031 and rotation angles and torque of joints 5033 so as to control, for example, the position and attitude of the endoscope 5001 held by the holding part 5032. This control can change the position or attitude of the endoscope 5001 to a desired position or attitude, makes it possible to insert the scope 5003 into the patient 5071, and can change the observed area in the body. The support device 5027 functions as an endoscope support arm for supporting the endoscope 5001 during the operation. Thus, the support device 5027 can play a role of a scopist who is an assistant holding the endoscope 5001. The support device 5027 may be a device for holding a microscope device 5301 to be described later, and can be called a medical support arm. The support device 5027 may be controlled using an autonomous control method by the arm control device 5045, or may be controlled using a control method in which the arm control device 5045 performs the control based on input of a user. The control method may be, for example, a master-slave method in which the support device 5027 serving as a slave device (replica device) that is a patient cart is controlled based on a movement of a master device (primary device) that is an operator console at a hand of the user. The support device 5027 may be remotely controllable from outside the operating room.

The example of the endoscope system 5000 to which the technology according to the present disclosure is applicable has been described above. For example, the technology according to the present disclosure may be applied to a microscope system.

### [Microscope System]

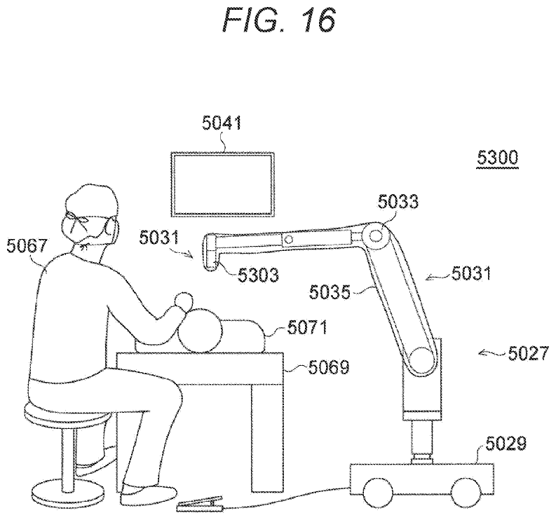

FIG. 16 is a diagram illustrating an example of a schematic configuration of a microscopic surgery system to which the technology according to the present disclosure is applicable. In the following description, the same components as those of the endoscope system 5000 will be denoted by the same reference numerals, and the description thereof will not be repeated.

FIG. 16 schematically illustrates a state in which the operator 5067 is performing surgery on the patient 5071 on the patient bed 5069 using a microscopic surgery system 5300. Note that, for the sake of simplicity, FIG. 16 does not illustrate a cart 5037 among the components of the microscopic surgery system 5300, and illustrates the microscope device 5301 instead of the endoscope 5001 in a simplified manner. The microscope device 5301 may refer to a microscope 5303 provided at the distal end of the links 5035, or may refer to the overall configuration including the microscope 5303 and the support device 5027.

As illustrated in FIG. 16, during the operation, the microscopic surgery system 5300 is used to display an image of a surgical site captured by the microscope device 5301 in a magnified manner on the display device 5041 installed in the operating room. The display device 5041 is installed in a position facing the operator 5067, and the operator 5067 performs various procedures, such as excision of an affected part, on the surgical site while observing the state of the surgical site using the image displayed on the display device 5041. The microscopic surgery system is used in, for example, ophthalmic operation and neurosurgical operation.

The respective examples of the endoscope system 5000 and the microscopic surgery system 5300 to which the technology according to the present disclosure is applicable have been described above. Systems to which the technology according to the present disclosure is applicable are not limited to such examples. For example, the support device 5027 can support, at the distal end thereof, another observation device or another surgical tool instead of the endoscope 5001 or the microscope 5303. Examples of the other applicable observation device include forceps, tweezers, a pneumoperitoneum tube for pneumoperitoneum, and an energy treatment tool for incising a tissue or sealing a blood vessel by cauterization. By using the support device to support the observation device or the surgical tool described above, the position thereof can be more stably fixed and the load of the medical staff can be lower than in a case where the medical staff manually supports the observation device or the surgical tool. The technology according to the present disclosure may be applied to a support device for supporting such a component other than the microscope.

The technology according to the present disclosure is suitably applicable to the surgical tools 5021 among the components described above. Specifically, by irradiating the affected site of the patient with a short-pulse laser pulse from the laser element 1 according to the present embodiment, it is possible to more safely and reliably treat the affected site without damaging the periphery of the affected site.

Note that the present technology can have the following configurations.
(1) A laser element including:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer; and
a second resonator that causes light of the second wavelength to resonate between the second reflection layer and the fourth reflection layer,
in which
the first resonator includes an optical element that condenses the light of the first wavelength in an optical axis direction, and
the optical axis of the laminated semiconductor layer, an optical axis of the laser medium, and an optical axis of the optical element are coaxially arranged.
(2) The laser element according to (1), in which the optical element includes a concave mirror.
(3) The laser element according to (2), in which the concave mirror has a multilayer film structure formed by layering at least one of a semiconductor material, a metal material, or a dielectric material.
(4) The laser element according to (2) or (3), in which at least one of the first reflection layer or the third reflection layer includes the concave mirror.
(5) The laser element according to any one of (2) to (4), in which
the laminated semiconductor layer includes a first semiconductor layer in which an end face on a side of the first reflection layer has a concave shape, and
the concave mirror is laminated on the first semiconductor layer.
(6) The laser element according to any one of (2) to (4), in which
an end face of the laser medium on a side of the third reflection layer has a concave shape, and
the concave mirror is laminated on the end face of the laser medium.
(7) The laser element according to any one of (2) to (4), in which the optical element is bonded to an end face of the laser medium on a side opposite to a side facing the laminated semiconductor layer.
(8) The laser element according to (7), in which
the optical element includes a first transparent material layer that transmits light of the second wavelength,
a first end face of the first transparent material layer bonded to the laser medium is a flat surface, and a second end face opposite to the first end face has a concave shape, and
the concave mirror is disposed along the second end face.
(9) The laser element according to (8), further including a second transparent material layer that is bonded to the second end face of the first transparent material layer and transmits the light of the second wavelength,
in which an end face of the second transparent material layer on a side opposite to a bonding surface to the first transparent material layer is a flat surface.
(10) The laser element according to (1), in which the optical element includes a light refracting member that refracts incident light in an optical axis direction.
(11) The laser element according to (10), in which
the laminated semiconductor layer includes a fifth reflection layer that is disposed closer to the laser medium than the active layer, and transmits a part of the light of the first wavelength, and
the light refracting member is disposed between the fifth reflection layer and the second reflection layer.
(12) The laser element according to (11), in which the light refracting member has an end face having a convex shape on a side of the laminated semiconductor layer facing the laser medium.
(13) The laser element according to (11), in which
the optical element is bonded to an end face of the laminated semiconductor layer on a side facing the laser medium, and
the light refracting member has one end face having a convex shape on a side facing the laser medium of the optical element.
(14) The laser element according to (13), in which
the optical element includes a transparent material layer that is bonded to the light refracting member and transmits light of the first wavelength,
the transparent material layer has a refractive index smaller than a refractive index of the light refracting member, and
a bonding surface of the transparent material layer to the light refracting member has a concave shape, an end face on an opposite side of the bonding surface is a flat surface, and an end face of the laser medium is bonded to the flat surface.
(15) The laser element according to (10), in which the light refracting member has an end face having a convex shape on a side of the laser medium facing the laminated semiconductor layer.
(16) The laser element according to (15), in which the second reflection layer is disposed along the end face of the convex shape.
(17) The laser element according to (15) or (16), in which
the optical element includes a transparent material layer that is bonded to the light refracting member and transmits light of the first wavelength, and
a bonding surface of the transparent material layer to the light refracting member has a concave shape, an end face on an opposite side of the bonding surface is a flat surface, and an end face of the laminated semiconductor layer is bonded to the flat surface.
(18) The laser element according to any one of (1) to (17), in which
a part of the semiconductor layer including the active layer in the laminated semiconductor layer is divided into a plurality of divided regions by an insulator, and
each of the plurality of divided regions includes the first resonator and the second resonator.

The laser element according to any one of (1) to (18), further including a saturable absorber that includes the fourth reflection layer on a third surface on a side opposite to the laser medium,
in which
the optical axis of the laminated semiconductor layer, the optical axis of the laser medium, an optical axis of the saturable absorber, and the optical axis of
the optical element are coaxially arranged, and the laminated semiconductor layer, the laser medium, and the saturable absorber are integrally bonded.
(20) An electronic device including:
a laser element; and
a control unit that performs control to emit light from the laser element,
in which
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer, and
a second resonator that causes light of the second wavelength to resonate between the second reflection layer and the fourth reflection layer,
the first resonator includes an optical element that condenses the light of the first wavelength in an optical axis direction, and
the optical axis of the laminated semiconductor layer, an optical axis of the laser medium, and an optical axis of the optical element are coaxially arranged.

Aspects of the present disclosure are not limited to the individual embodiments described above, but include various modifications that can be conceived by those skilled in the art, and the effects of the present disclosure are not limited to the contents described above. That is, various additions, modifications, and partial deletions are possible without departing from the conceptual idea and spirit of the present disclosure derived from the matters defined in the claims and equivalents thereof.

### REFERENCE SIGNS LIST

1 Laser element
2 Laminated semiconductor layer
2 Excitation light source
3 Solid-state laser medium
4 Saturable absorber
5 n-GaAs substrate
6 Cladding layer
7 Active layer
8 Cladding layer
9 Optical element
10 Concave mirror
10a Concave mirror
10b Concave mirror
11 First resonator
12 Second resonator
13 Base material
18 Laser array
21 Resist film
22 Photomask
23 Protrusion
24 Multilayer film
25 Alignment mark
26 Camera
27 First transparent medium
28 Second transparent medium
31 Contact layer
32 Oxide layer (e.g., Al2O3 layer)
33 Contact layer
34 Insulating film
41 Concave mirror formation layer
42 Multilayer film
42a Multilayer film
42b Multilayer film
43 Transparent material layer
44 Non-reflection coating layer
46 Light refracting member
47 Transparent material layer

1. A laser element comprising:
a laminated semiconductor layer including a first reflection layer with respect to a first wavelength and an active layer that performs surface emission at the first wavelength;
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface;
a fourth reflection layer with respect to the second wavelength, the forth reflection layer being disposed on the second surface or disposed on a rear side of the optical axis with respect to the second surface;
a first resonator that causes light of the first wavelength to resonate between the first reflection layer and the third reflection layer; and
a second resonator that causes light of the second wavelength to resonate between the second reflection layer and the fourth reflection layer,
wherein
the first resonator includes an optical element that condenses the light of the first wavelength in an optical axis direction, and
the optical axis of the laminated semiconductor layer, an optical axis of the laser medium, and an optical axis of the optical element are coaxially arranged.

2. The laser element according to claim 1, wherein the optical element includes a concave mirror.

3. The laser element according to claim 2, wherein the concave mirror has a multilayer film structure formed by layering at least one of a semiconductor material, a metal material, or a dielectric material.

4. The laser element according to claim 2, wherein at least one of the first reflection layer or the third reflection layer includes the concave mirror.

5. The laser element according to claim 2, wherein
the laminated semiconductor layer includes a first semiconductor layer in which an end face on a side of the first reflection layer has a concave shape, and
the concave mirror is laminated on the first semiconductor layer.

6. The laser element according to claim 2, wherein
an end face of the laser medium on a side of the third reflection layer has a concave shape, and
the concave mirror is laminated on the end face of the laser medium.

7. The laser element according to claim 2, wherein the optical element is bonded to an end face of the laser medium on a side opposite to a side facing the laminated semiconductor layer.

8. The laser element according to claim 7, wherein
the optical element includes a first transparent material layer that transmits light of the second wavelength,
a first end face of the first transparent material layer bonded to the laser medium is a flat surface, and a second end face opposite to the first end face has a concave shape, and
the concave mirror is disposed along the second end face.

9. The laser element according to claim 8, further comprising a second transparent material layer that is bonded to the second end face of the first transparent material layer and transmits the light of the second wavelength,
wherein an end face of the second transparent material layer on a side opposite to a bonding surface to the first transparent material layer is a flat surface.

10. The laser element according to claim 1, wherein the optical element includes a light refracting member that refracts incident light in an optical axis direction.

11. The laser element according to claim 10, wherein
the laminated semiconductor layer includes a fifth reflection layer that is disposed closer to the laser medium than the active layer, and transmits a part of the light of the first wavelength, and
the light refracting member is disposed between the fifth reflection layer and the second reflection layer.

12. The laser element according to claim 11, wherein the light refracting member has an end face having a convex shape on a side of the laminated semiconductor layer facing the laser medium.

13. The laser element according to claim 11, wherein
the optical element is bonded to an end face of the laminated semiconductor layer on a side facing the laser medium, and
the light refracting member has one end face having a convex shape on a side facing the laser medium of the optical element.

14. The laser element according to claim 13, wherein
the optical element includes a transparent material layer that is bonded to the light refracting member and transmits light of the first wavelength,
the transparent material layer has a refractive index smaller than a refractive index of the light refracting member, and
a bonding surface of the transparent material layer to the light refracting member has a concave shape, an end face on an opposite side of the bonding surface is a flat surface, and an end face of the laser medium is bonded to the flat surface.

15. The laser element according to claim 10, wherein the light refracting member has an end face having a convex shape on a side of the laser medium facing the laminated semiconductor layer.

16. The laser element according to claim 15, wherein the second reflection layer is disposed along the end face of the convex shape.

17. The laser element according to claim 15, wherein
the optical element includes a transparent material layer that is bonded to the light refracting member and transmits light of the first wavelength, and
a bonding surface of the transparent material layer to the light refracting member has a concave shape, an end face on an opposite side of the bonding surface is a flat surface, and an end face of the laminated semiconductor layer is bonded to the flat surface.

18. The laser element according to claim 1, wherein
a part of the semiconductor layer including the active layer in the laminated semiconductor layer is divided into a plurality of divided regions by an insulator, and
each of the plurality of divided regions includes the first resonator and the second resonator.

19. The laser element according to claim 1, further comprising a saturable absorber that includes the fourth reflection layer on a third surface on a side opposite to the laser medium,
wherein
the optical axis of the laminated semiconductor layer, the optical axis of the laser medium, an optical axis of the saturable absorber, and the optical axis of the optical element are coaxially arranged, and
the laminated semiconductor layer, the laser medium, and the saturable absorber are integrally bonded.

20. An electronic device comprising:
a laser element; and
a control unit that performs control to emit light from the laser element,
wherein
the laser element includes
a laminated semiconductor layer including a first reflection layer with respect to a first wavelength and an active layer that performs surface emission at the first wavelength,
a laser medium disposed on a rear side of an optical axis of the laminated semiconductor layer and including a second reflection layer with respect to a second wavelength on a first surface facing the laminated semiconductor layer, and a third reflection layer with respect to the first wavelength on a second surface on a side opposite to the first surface,
a fourth reflection layer with respect to the second wavelength, the forth reflection layer being disposed on the second surface or disposed on a rear side of the optical axis with respect to the second surface,
a first resonator that causes light of the first wavelength to resonate between the first reflection layer and the third reflection layer, and
a second resonator that causes light of the second wavelength to resonate between the second reflection layer and the fourth reflection layer,
the first resonator includes an optical element that condenses the light of the first wavelength in an optical axis direction, and
the optical axis of the laminated semiconductor layer, an optical axis of the laser medium, and an optical axis of the optical element are coaxially arranged.
